(19) United States
(12) Patent Application Publication
(10) Pub. No.: US 2013/0161805 A1
(43) Pub. Date: Jun. 27, 2013

(54) INTEGRATED CIRCUIT (IC) LEADFRAME DESIGN

(71) Applicants: Clifford R. Fishley, San Jose, CA (US); John J. Krantz, Northampton, PA (US); Abiola Awujoola, Pleasanton, CA (US); Allen S. Lim, San Jose, CA (US); Stephen M. King, Hamburg, PA (US); Lawrence W. Golick, Nazareth, PA (US); Ashley Rebelo, Allentown, PA (US)

(72) Inventors: Clifford R. Fishley, San Jose, CA (US); John J. Krantz, Northampton, PA (US); Abiola Awujoola, Pleasanton, CA (US); Allen S. Lim, San Jose, CA (US); Stephen M. King, Hamburg, PA (US); Lawrence W. Golick, Nazareth, PA (US); Ashley Rebelo, Allentown, PA (US)

(73) Assignee: LSI Corporation, Milpitas, CA (US)

(21) Appl. No.: 13/333,604

(22) Filed: Dec. 21, 2011

(51) Int. Cl. H01L 23/495; H05K 3/30

(52) U.S. Cl. 257/676; 29/832; 257/E23.031

(57) ABSTRACT

Provided, in one embodiment, is an integrated circuit (IC) leadframe. In one example, the leadframe includes a paddle, wherein the paddle has a surface configured to accept an IC chip and has at least one edge, the at least one edge having one or more slots located therein. In this example, the leadframe may further include a plurality of lead fingers having ends extending toward the at least one edge, wherein the ends of ones of pairs of adjacent lead fingers extend into corresponding slots in the paddle.

### TECHNICAL FIELD

This application is directed, in general, to an integrated circuit (IC) leadframe and, more specifically, to an IC leadframe having one or more pairs of lead fingers extending into corresponding slots in the paddle.

### BACKGROUND

Wire-bonding technology for integrated circuit packages remains a staple in IC manufacturing. For high pin count devices with fine pitch it allows an element of precision that is difficult to match with flip-chip solder bump technology. Typical high-pin count packages, for example thin quad flat pack TQFP packages, have a square or rectangular paddle, on which the IC chip is bonded, with leads extending from the four sides. In state-of-the-art high-speed digital devices the length and configuration of the wire bonds and the leadframe fingers to which the wire bonds are attached adds a circuit element that needs to be controlled for optimum performance. A variety of leadframe designs have been developed to address these issues but improvements are continually sought.

### SUMMARY

One aspect provides an integrated circuit (IC) leadframe. In one example, the leadframe includes a paddle, wherein the paddle has a surface configured to accept an IC chip and has at least one edge, the at least one edge having one or more slots located therein. In this example, the leadframe may further include a plurality of lead fingers having ends extending toward the at least one edge, wherein the ends of ones of pairs of adjacent lead fingers extend into corresponding slots in the paddle.

Another aspect provides a method for manufacturing an IC leadframe. In one example, the method includes forming a paddle, wherein the paddle has a surface configured to accept an IC chip and has at least one edge, the at least one edge having one or more slots located therein. In this example, the method further includes creating a plurality of lead fingers having ends extending toward the at least one edge, wherein the ends of ones of pairs of adjacent lead fingers extend into corresponding slots in the paddle.

Yet another aspect provides an IC package. In one example, the IC package includes: 1) a paddle having at least one edge, the at least one edge having one or more slots located therein, 2) an IC chip secured to a surface of the paddle, 3) a plurality of lead fingers having ends extending toward the at least one edge, wherein the ends of ones of pairs of adjacent lead fingers extend into corresponding slots in the paddle, and 4) a plurality of wire bonds electrically connecting the plurality of lead fingers to bond pads of the IC chip.

### BRIEF DESCRIPTION

Reference is now made to the following descriptions taken in conjunction with the accompanying drawings, in which:

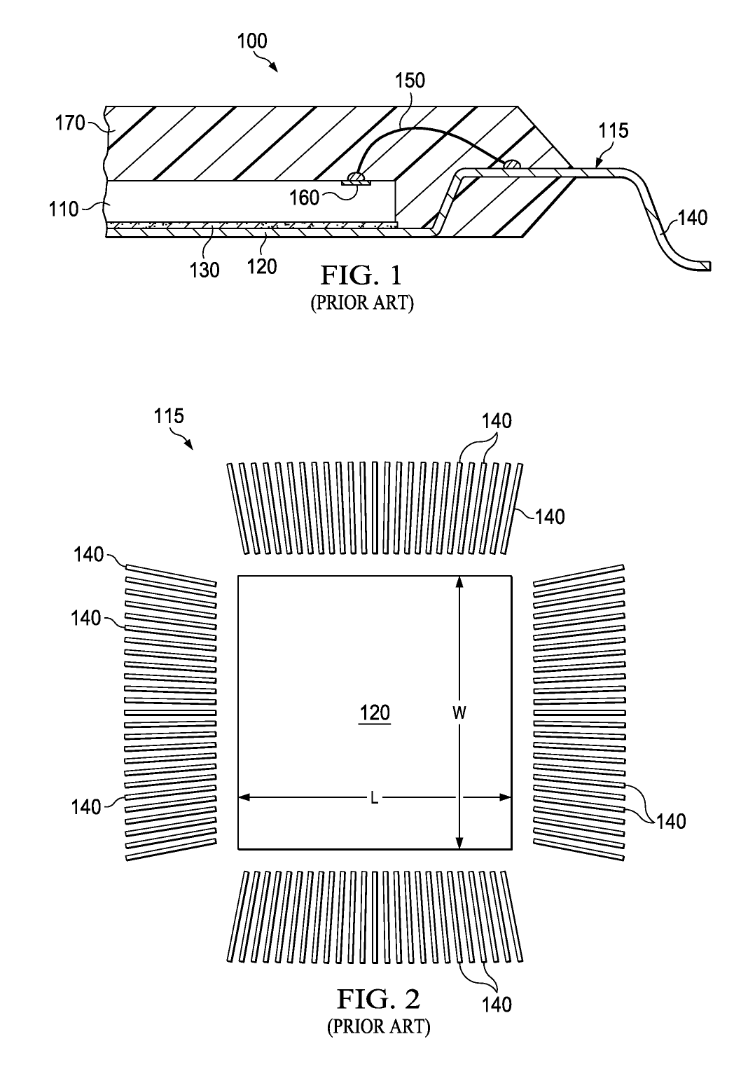

FIGS. 1-4 illustrate various different views of Prior Art integrated circuit (IC) packages;

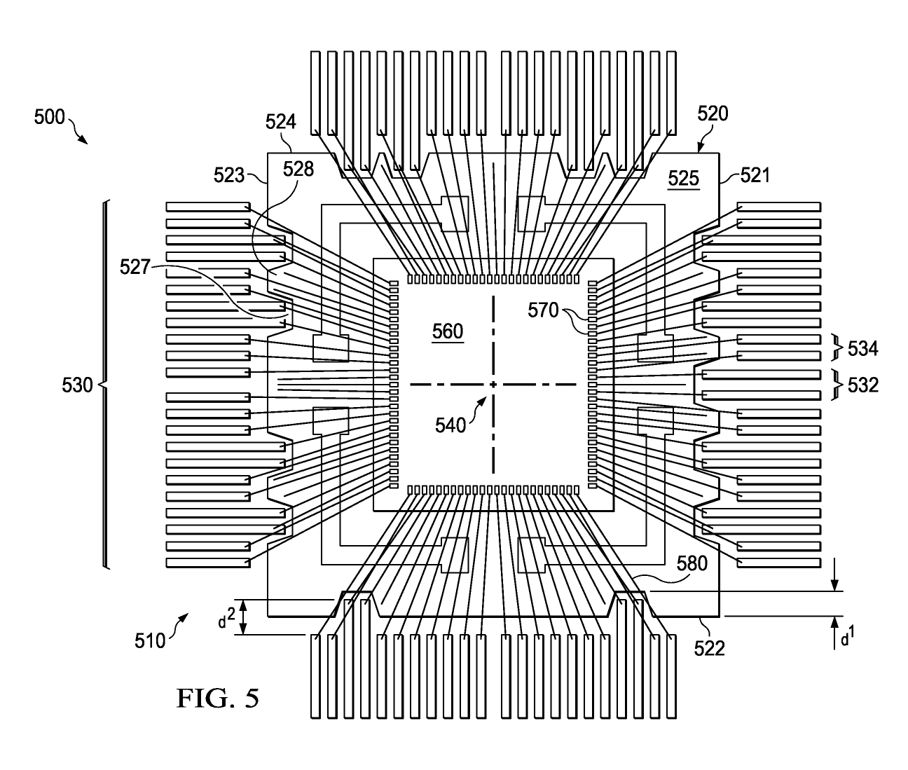

FIG. 5 illustrates a plan view of one embodiment of an IC package manufactured in accordance with the disclosure; and

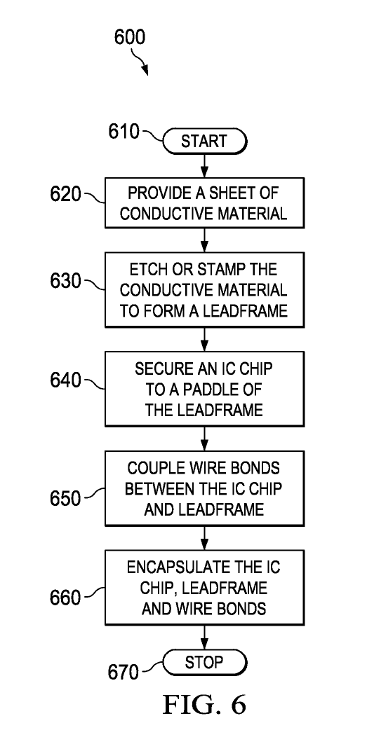

FIG. 6 illustrates a flow diagram of one process for manufacturing an IC package in accordance with the disclosure.

### DETAILED DESCRIPTION

The present disclosure is based, at least in part, on the acknowledgment that to achieve high speed signals and data rates successfully, while maintaining good signal quality, shorter paths between lead fingers and the bond pads of the semiconductor die are needed. The present disclosure is further based, at least in part, on the acknowledgment that as IC data communication rates increase, it becomes increasingly difficult to maintain signal integrity. For example, as the chip data rates increase, the rate of change of voltage with respect to time (dv/dt) also increases. With rising dv/dt, there is increased induction of unwanted signals on adjacent nets in the package, creating crosstalk. The induced crosstalk on a given net distorts the original signal of that net. Accordingly, as the distortion increases, the receiving circuit is less able to detect a logic 1 or a logic 0, and data corruption may occur.

Based upon the foregoing acknowledgements, the present disclosure recognizes that by creating slots within the leadframe paddle, and extending pairs of adjacent lead fingers into corresponding slots, shorter paths between the lead fingers and the semiconductor die may be achieved. With this design, higher speed signals and data rates can be successfully achieved.

Furthermore, extending the pairs of adjacent lead fingers into slots in the paddle, creates a staggered lead finger configuration. Accordingly, a situation wherein the associated bond wires are physically spaced further apart from one another is created. This increased physical spacing may exist in both the horizontal direction, as well as the vertical direction, and is also helpful in reducing crosstalk.

The disclosure will be illustrated and described using an exposed paddle thin quad flat pack integrated circuit (IC) package (eTQFP) as a prototype. However, it should be understood that the disclosure is not so limited. It may apply to a variety of wire-bonded IC devices. Typically these will be overmolded plastic packages, as in the example illustrated here, or may be plastic cavity packages, or any other type of high pin count packaging. Also considered within the scope of the disclosure are IC or electrical component packages in which the configuration is modified to influence other aspects of the electrical performance of the device. The package may contain hybrid ICs or integrated passive device (IPD) chips. It may also contain optical sub-assemblies such as MEMS devices packaged with digital chips.

With reference to FIG. 1, illustrated is a prior art integrated circuit (IC) package 100. The IC package 100, as shown, includes an IC chip 110 bonded to a leadframe 115. The leadframe 115 comprises a paddle 120 with solder, or conductive adhesive, 130 as the medium for bonding the IC chip 110 to the paddle 120. In this package design, the paddle 120 is exposed on the bottom of the package to allow a ground I/O connection to be made directly to the exposed paddle 120. The leadframe 115 also comprises lead fingers 140 extending from the side of the package toward the paddle 120. This form of semiconductor device package is characterized by wire bonds 150 bonded between bond pads 160 on the IC chip 110 and the lead fingers 140. FIG. 1 also illustrates a plastic encapsulant 170.

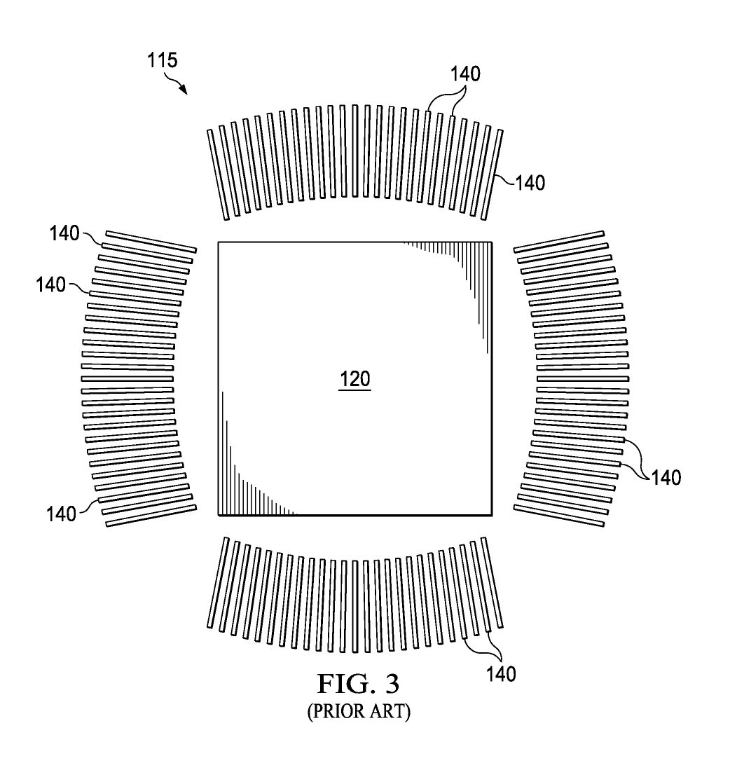

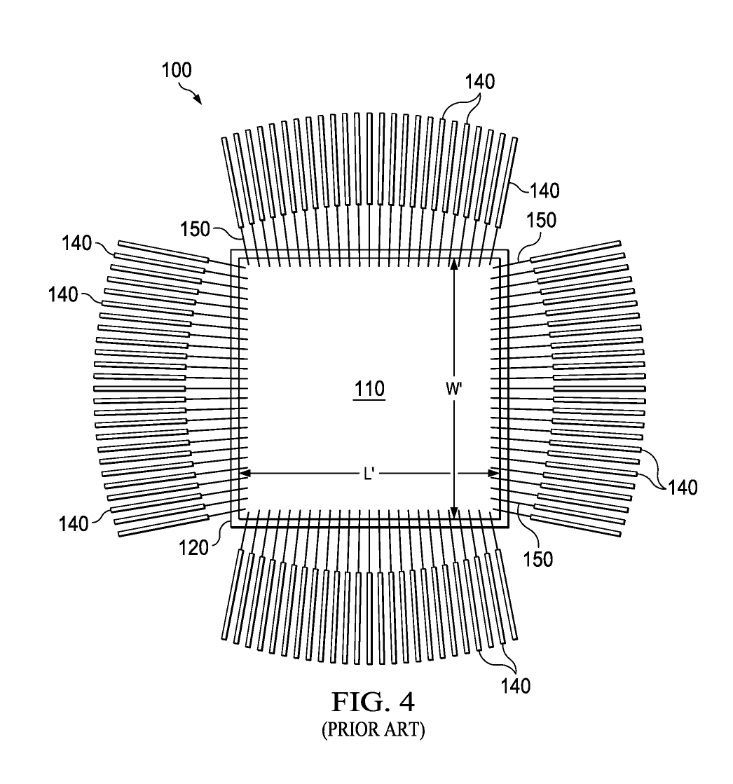

FIG. 2 is a plan view of the leadframe 115 of FIG. 1 that schematically shows the organization of the lead fingers 140 that extend toward the paddle 120. The lead fingers 140 in this design are fanned. The fanned array provides approximately equal wire bonds lengths. The paddle 120 typically has a square shape, with four edges as shown. In the general case the paddle has a quadrilateral shape, with length L, width W, and four edges. In FIG. 2, the plurality of lead fingers 140 extends toward the paddle 120 along the four edges. Other designs are possible, but the lead fingers 140 will often extend toward at least two edges. FIG. 3 illustrates a leadframe similar to that of FIG. 2; however, in this example the lead fingers 140 are curved about each side of the leadframe 115.

FIG. 4 illustrates the leadframe of FIG. 3 with the IC chip 110 die bonded to the paddle 120. The IC chip 110 in this design, has a square shape but, again, in the general case the IC chip has a quadrilateral shape with length L′, width W′, wherein L′ is less than L (of the paddle 120) and W′ is less than W (of the paddle 120), and wherein the IC chip 110 substantially covers the paddle 120 except for the exposed regions along the edge of the paddle 120. (The exposed regions are a consequence of L′ and W′ being less than L and W, respectively.) FIG. 4 also shows the wire bonds 150 between the IC chip 110 and the lead fingers 140. Due to the fanning of the lead fingers, and the curved configuration of the array of lead fingers, the length of all of the wire bonds in the array is approximately equal.

FIG. 5 illustrates a plan view of one embodiment of an IC package 500 manufactured in accordance with the disclosure. The IC package 500 illustrated in the embodiment of FIG. 5 initially includes an IC leadframe 510. In the example embodiment of FIG. 5, the IC leadframe 510 includes a paddle 520. The term “paddle” as used herein, is a well-known term in the art designed to reference a feature upon which an IC chip may be bonded. The paddle 520, in the embodiment of FIG. 5, includes at least one edge. For example, the paddle 520 illustrated in the embodiment of FIG. 5 is quadrilateral in shape, and thus has four edges 521, 522, 523, 524. A portion of the paddle 520, in the illustrated embodiment of FIG. 5, comprises a connecting bar 525. The term “connecting bar” as used herein, is a well-known term in the art designed to reference an area in the IC leadframe 510 that provides a common connection point for one of the common nets in the package (e.g., typically VSS or Ground). Wires from the die can be bonded to this connecting bar 525. The connecting bar can be at a different elevation in the IC leadframe 510 with respect to the part of the paddle 520 that is under the die. Often the connecting bar 525, is at the same elevation as the lead tips and higher than the area of the paddle 520, under the die. Other paddle 520 designs exist, including those that do not include the separate connecting bar 525.

The paddle 520, in accordance with the disclosure, includes one or more slots 527 located therein. In fact, in the embodiment of FIG. 5, the slots 527 are located proximate an outer perimeter of all four edges 521, 522, 523, 524. While the slots 527 are illustrated in FIG. 5 as being located in the connecting bar 525, other embodiments (particularly embodiments wherein the paddle 520 does not include the connecting bar 525) may exist wherein the slots 527 are located elsewhere. Additionally, while the embodiment of FIG. 5 illustrates that the slots 527 are located along all four edges 521, 522, 523, 524, the slots 527 may be located along fewer than all the edges of the paddle 520. The slots 527, in the illustrated embodiment, create one or more posts 528 in the paddle 520. As those skilled in the art are aware, the paddle 520 may be electrically coupled to a ground pin, voltage pin, etc. and remain within the purview of the disclosure. In the particular embodiment of FIG. 5, the paddle 520 is electrically coupled to a ground pin.

The leadframe 510 illustrated in FIG. 5 further includes a plurality of lead fingers 530. The plurality of lead fingers 530 have ends that extend toward one or more edges of the paddle 520. In the illustrated embodiment of FIG. 5, the ends of the plurality of lead fingers 530 extend toward all four edges 521, 522, 523, 524 of the paddle 520. Nevertheless, other embodiments may exist wherein the ends of the plurality of lead fingers 530 extend toward fewer than all edges of the paddle 520.

In accordance with the disclosure, ends of pairs of adjacent lead fingers 532 extend into the corresponding slots 527 in the paddle 520. In the embodiment of FIG. 5, the ends of pairs of adjacent lead fingers 532 extend into the corresponding slots 527 in the connection bar 525 portion of the paddle 520. The phrase “pair of adjacent lead fingers”, as that term is used with regard to the lead fingers 530 that extend into the slots 527, is intended to represent lead fingers that couple to differential pairs of conductors. For example, the differential pairs might be a set of two individual conductor traces that are usually next to each other as they route through the package. For example, the differential pairs might be used to carry high speed signals. In one example, the buffer that supplies the signal to the differential pairs applies a negative going signal on one of the conductors and a positive going signal on the other conductor. The magnetic and electrical fields generated as the wave fronts travel along the traces are mitigated as the fields generated from the positive going edge cancels with the fields generated from the negative going edge. As additionally illustrated in the embodiment of FIG. 5, one or more posts 528 interpose ends of flanking pairs of adjacent lead fingers 532.

The number, location, etc. of the pairs of adjacent lead fingers 532 that extend into the corresponding slots 527 in the paddle 520 may vary greatly by embodiment and configuration. The pairs of adjacent lead fingers 532 that extend into the slots 527 may be staggered proximate a centerline 540 of the paddle, wherein the other lead fingers 534 that do not extend into the slots 527 are staggered distal the centerline 540. For example, focusing on the first edge 521 of the paddle 520, the pairs of adjacent lead fingers 532 that extend into the slots 527 (e.g., those proximate the centerline 540) are alternately staggered with pairs of the other lead fingers 534 that do not extend into the slots 527 (e.g., those distal the centerline 540). In the embodiment of FIG. 5, the pairs of adjacent lead fingers 532 that extend into the slots 527 and the pairs of the other lead fingers 534 that do not extend into the slots 527 are staggered across the entire length of the edge 521. The term “alternately staggered”, as used herein, is intended to exclude those configurations such as shown in FIGS. 2 and 3, wherein the lead fingers are fanned and/or curved.

In another example, focusing on the second edge 522 of the paddle 520, only two pairs of adjacent lead fingers 532 extend into the slots 527, whereas all the other lead fingers 534 along that edge remain staggered distal the centerline 540. In fact, the two pairs of adjacent lead fingers 532 that extend into the slots 527 along the edge 522 are located at opposite corners thereof. In one common embodiment, at least two pairs of adjacent lead fingers 532 extend into the slots 527 on a given edge.

In another example, focusing on the third edge 523 of the paddle 520, a significant number, but less than all, of the pairs of adjacent lead fingers 532 extend into the slots 527. In yet another example, focusing on the fourth edge 524, individual ones of the other lead fingers 534 that do not extend into the slots 527 interpose flanking ones of pairs of adjacent lead fingers 532 extending into the slots 527. Accordingly, wherein the configurations depicted with regard to edges 521, 522, 523 employ two or more other lead fingers 534 that do not extend into the slots 527 between each of the flanking pairs of adjacent lead fingers, the embodiment depicted with regard to edge 524 employs only one other lead finger 534 between each of the flanking pairs of adjacent lead fingers 532. The configuration and layout of the lead fingers 530 illustrated in FIG. 5 are but one of many configurations and layouts that may fall within the scope of this disclosure. Also, while the embodiment of FIG. 5 illustrates that each edge has a different lead finger 530 configuration, certain other embodiments exist wherein each edge has the same lead finger 530 configuration.

The size of the slots 530, and more particularly the depth (d¹) of the slots 530, may vary by embodiment, as well as the design of the paddle 520. For example, in one embodiment the depth (d¹) ranges from about 0.4 mm to about 1.5 mm, and in another particular embodiment the depth (d¹) ranges from about 0.5 mm to about 1.0 mm. Other depth (d¹) values, however, are within the scope of this disclosure, and will depend on many factors that will change and scale as the technology develops. For example, as the width of the connecting bar 525 reduces, it is likely that the depth (d¹) of the slots 530 may also reduce. It should also be noted that the depth (d¹) need not be fixed across the entire IC package 500, or for that matter across an entire side of the paddle 520. Accordingly, embodiments may exist wherein the depth (d¹) varies within the IC package 500.

The degree of stagger (e.g., proximate and distal the centerline 540) amongst lead fingers 530 will likely depend on the design of the slots 527. For example, certain embodiments exist wherein the pairs of adjacent lead fingers 532 that extend into the slots 527 will be staggered with respect to the other lead fingers 534 that do not extend into the slots 527 by a distance (d²) that is slightly greater than the depth (d¹). This represents but one embodiment. Other embodiments may exist, however, where the correlation between the depth (d¹) and the distance (d²) is not so direct.

Secured to the paddle 520 in the embodiment of FIG. 5 is an IC chip 560. The IC chip 560, in one embodiment, might be an IC chip as used in disk drive SoC's (system on chip) and gigabit PHY interface devices, among others. The IC chip 560, in the particular embodiment shown, may include bond pads 570. Additionally, a plurality of wire bonds 580 may electrically connect the lead fingers 530 to the bond pads 570. As additionally shown, the wire bonds 580 may also electrically connect the paddle 520 to various bond pads 570 of the IC chip 560. In the illustrated embodiment, certain ones of the wire bonds 580 electrically connect the bond pads 570 to the posts 528 of the paddle 520.

Paddle designs consistent with those of this disclosure have many benefits over traditional designs. First, paddle designs manufactured in accordance with the disclosure are configured to bring ones of the lead fingers (e.g., pairs of adjacent lead fingers) close to the paddle, thus reducing the distance between the centerline of the paddle and the fingers. As disclosed, the slots in the paddle allow for the reduced distance. Moreover, with the reduced distance, shorter bond wires can be used to electrically couple the bond pads and the lead fingers. The shorter bond wires, advantageously, reduce the inductance thereof, thereby lowering the crosstalk in the package. Accordingly, higher speed signal and data rates may be achieved than traditional designs.

Turning briefly to FIG. 6, illustrated is a flow diagram 600 depicting one process for manufacturing an IC package in accordance with the disclosure. The flow diagram 600 begins in a start step 610. Thereafter, in a step 620, a sheet of conductive material is provided. The sheet of conductive material, as those skilled in the art appreciate, may be any conductive material currently known or hereafter discovered for use in leadframes. In a step 630, the sheet of conductive material is etched, stamped, etc. The step of etching or stamping the sheet of conductive material defines the different features of the leadframe discussed above with regard to FIG. 5. For example, the resulting leadframe might have a paddle with slots, as well as a plurality of lead fingers, wherein the ends of ones of pairs of adjacent lead fingers extend into corresponding slots in the paddle. Those skilled in the art understand the general process for forming the leadframe, as well as that the resulting leadframe may be any configuration consistent with this disclosure.

Thereafter, in a step 640, an IC chip may be secured to the paddle of the leadframe. Suitable adhesives, whether conductive or not, may be used to secure the IC chip. In a step 650, wire bonds may be coupled between bond pads on the IC chip and the various different features of the leadframe. For example, certain wire bonds may couple ones of bond pads to the paddle (including the posts within the paddle), and other wire bonds may couples ones of bond pads to the lead fingers (including the pairs of adjacent lead fingers extending into the corresponding slots in the paddle). Those skilled in the art understand the process for bonding the wire bonds to the various features. Thereafter, in a step 660, an encapsulant may be formed over the IC chip, leadframe, and wire bonds. The manufacturing process might then end in a stop step 670.

Various additional modifications (e.g., further additions, deletions, substitutions) of this disclosure may occur to those skilled in the art. All deviations from the specific teachings of this specification that basically rely on the principles and their equivalents through which the art has been advanced are properly considered within the scope of the disclosure as described and claimed.

What is claimed is:

1. An integrated circuit (IC) leadframe, comprising:
a paddle, wherein the paddle has a surface configured to accept an IC chip and has at least one edge, the at least one edge having one or more slots located therein; and
a plurality of lead fingers having ends extending toward the at least one edge, wherein the ends of ones of pairs of adjacent lead fingers extend into corresponding slots in the paddle.

2. The IC leadframe as recited in claim 1, wherein a portion of the paddle is a connecting bar, and further wherein the ends of ones of pairs of adjacent lead fingers extend into corresponding slots in the connecting bar portion of the paddle.

3. The IC leadframe as recited in claim 1, wherein the slots create one or more posts within the paddle, the one or more posts interposing the ones of pairs of adjacent lead fingers extending into the corresponding slots.

4. The IC leadframe as recited in claim 1, wherein the ones of pairs of adjacent lead fingers extending into the corresponding slots are staggered proximate a centerline of the paddle, and further including other lead fingers of the plurality of lead fingers extending toward the at least one edge that are staggered distal the centerline.

5. The IC leadframe as recited in claim 4, wherein the distal staggered lead fingers are staggered in pairs.

6. The IC leadframe as recited in claim 5, wherein the pairs of proximately staggered lead fingers and distally staggered lead fingers are alternately staggered.

7. The IC leadframe as recited in claim 6, wherein the pairs of proximately staggered lead fingers and distally staggered lead fingers are alternately staggered across an entire portion of the at least one edge.

8. The IC leadframe as recited in claim 6, wherein the pairs of proximately staggered lead fingers and distally staggered lead fingers are alternately staggered across less than an entire portion of the at least one edge.

9. The IC leadframe as recited in claim 4, wherein individual ones of the distal staggered lead fingers interpose flanking ones of pairs of adjacent lead fingers extending into the corresponding slots.

10. The IC leadframe as recited in claim 1, wherein the paddle has a quadrilateral shape having four edges, and further wherein a plurality of lead fingers having ends extend toward each of the four edges, and further wherein the ends of ones of pairs of adjacent lead fingers extend into corresponding slots in each of the four edges of the paddle.

11. A method for manufacturing an integrated circuit (IC) leadframe, comprising:
forming a paddle, wherein the paddle has a surface configured to accept an IC chip and has at least one edge, the at least one edge having one or more slots located therein; and
creating a plurality of lead fingers having ends extending toward the at least one edge, wherein the ends of ones of pairs of adjacent lead fingers extend into corresponding slots in the paddle.

12. The method as recited in claim 11, wherein a portion of the paddle is a connecting bar, and further wherein the ends of ones of pairs of adjacent lead fingers extend into corresponding slots in the connecting bar portion of the paddle.

13. The method as recited in claim 11, wherein the slots create one or more posts within the paddle, the one or more posts interposing the ones of pairs of adjacent lead fingers extending into the corresponding slots.

14. The method as recited in claim 11, wherein the ones of pairs of adjacent lead fingers extending into the corresponding slots are staggered proximate a centerline of the paddle, and further including other lead fingers of the plurality of lead fingers extending toward the at least one edge that are staggered distal the centerline.

15. The method as recited in claim 14, wherein the distal staggered lead fingers are staggered in pairs.

16. The method as recited in claim 15, wherein the pairs of proximately staggered lead fingers and distally staggered lead fingers are alternately staggered.

17. The method as recited in claim 16, wherein the pairs of proximately staggered lead fingers and distally staggered lead fingers are alternately staggered across an entire portion of the at least one edge.

18. The method as recited in claim 16, wherein the pairs of proximately staggered lead fingers and distally staggered lead fingers are alternately staggered across less than an entire portion of the at least one edge.

19. The method as recited in claim 14, wherein individual ones of the distal staggered lead fingers interpose flanking ones of pairs of adjacent lead fingers extending into the corresponding slots.

20. The IC leadframe as recited in claim 11, wherein forming a paddle includes forming a paddle having a quadrilateral shape having four edges, and further wherein a plurality of lead fingers having ends extend toward each of the four edges, and further wherein the ends of ones of pairs of adjacent lead fingers extend into corresponding slots in each of the four edges of the paddle.

21. An integrated circuit (IC) package, comprising a paddle having at least one edge, the at least one edge having one or more slots located therein;
an IC chip secured to a surface of the paddle;
a plurality of lead fingers having ends extending toward the at least one edge, wherein the ends of ones of pairs of adjacent lead fingers extend into corresponding slots in the paddle; and
a plurality of wire bonds electrically connecting the plurality of lead fingers to bond pads of the IC chip.

22. The IC package as recited in claim 21, wherein the slots create one or more posts within the paddle, the one or more posts interposing the ones of pairs of adjacent lead fingers extending into the corresponding slots.

23. The IC package as recited in claim 22, wherein ones of the plurality of wire bonds electrically connect ones of the bond pads of the IC chip to the one or more posts.

24. The IC package as recited in claim 21, wherein the ones of pairs of adjacent lead fingers extending into the corresponding slots are staggered proximate a centerline of the paddle, and further including other lead fingers of the plurality of lead fingers extending toward the at least one edge that are staggered distal the centerline.

25. The IC package as recited in claim 24, wherein the distal staggered lead fingers are staggered in pairs.

26. The IC package as recited in claim 25, wherein the pairs of proximately staggered lead fingers and distally staggered lead fingers are alternately staggered.

27. The IC package as recited in claim 26, wherein the pairs of proximately staggered lead fingers and distally staggered lead fingers are alternately staggered across an entire portion of the at least one edge.
